(19) United States
(12) Patent Application Publication
(10) Pub. No.: US 2004/0009667 A1
(43) Pub. Date: Jan. 15, 2004

(54) Etching method

(76) Inventors: Etsuo Iijima, Yamanashi (JP); Akiteru Koh, Yamanashi (JP)

Correspondence Address: Finnegan, Henderson, Farabow,, Garrett & Dunner, L.L. P., 1300 I Street, N.W., Washington, DC, 20005-3315, US

(21) Appl. No.: 10/359,066

(22) Filed: Feb. 6, 2003

(30) Foreign Application Priority Data
Feb. 7, 2002 (JP) JP2002-31047

(51) Int. Cl. H01L 21/302; H01L 21/461

(52) U.S. Cl. 438/689

(57) ABSTRACT

When simultaneously etching areas such as an n-type area and a p-type area doped with different dopants or having different dope quantities, the inconsistency in the shapes of elements formed at the individual areas is minimized and the occurrence of a gate oxide film breakdown is prevented by first executing a main etching step (first etching step) during which, a polysilicon film layer 204 is etched until a gate oxide film 202 becomes partially exposed by setting the pressure inside a processing chamber to 20 mTorr or lower, setting the high-frequency power applied to a lower electronic to 0.15 W/cm² or higher, supplying a processing gas containing at least HBr gas into the processing chamber and using mask patterns as masks and then executing an over-etching step (a second etching step) during which N₂ gas is added into the processing gas and any remaining portions of the polysilicon film layer left unetched during the main etching step are removed through etching.

### BACKGROUND OF THE INVENTION

The present invention relates to an etching method and, more specifically, it relates to an etching method ideal in an application that requires areas processed with different dopants or at different dope quantities to be etched simultaneously.

### DESCRIPTION OF THE RELATED ART

A dual gate structure achieved by forming areas with different dopants on a single substrate, e.g., an n-type area doped with an n-type impurity such as phosphorus (P) and a p-type area doped with a p-type impurity such as boron (B) or a p-type area with no dopant and forming gate electrodes at these areas is sometimes adopted to realize higher speed in semiconductor elements including memory and logic elements.

In such a dual gate structure, the gate electrodes are formed at the individual areas by etching a film structure such as that shown in FIG. 4A with a plasma processing apparatus having an upper electrode and a lower electrode facing opposite each other provided in, for instance, an airtight processing chamber and capable of applying high-frequency power to the upper and lower electrodes. The film structure includes an n-type area 14a and a p-type area 14b formed by selectively doping the impurities mentioned above on a polysilicon film 14 constituted of a poly-crystal silicon and formed over a gate oxide film 12 which, in turn, is formed over a silicon substrate 10 and mask patterns 16a and 16b constituted of, for instance, a reflection-reducing film and resist film, formed over the n-type area and the p-type area respectively.

Plasma processing is executed in order to simultaneously etch the n-type area 14a and the p-type area 14b in this film structure by using the mask patterns 16a and 16b as masks and supplying a processing gas which may be HBr gas, a mixed gas constituted of HBr gas and O₂ gas or a mixed gas constituted of Cl₂ gas and HBr gas into the airtight processing chamber in the related art.

During this process, the gate electrodes mentioned above, for instance, are formed by etching the film structure until the gate oxide film 12 at the base becomes exposed (FIG. 4B) and over-etching any excess portions having remained unetched (see FIG. 4C).

However, there is a problem with simultaneously etching the n-type area 14a and the p-type area 14b at the polysilicon film layer 14 through this plasma etching method in the related art in that there is inconsistency between the shape of the gate electrode formed at the n-type area 14a and the shape of the gate electrode formed at the p-type area 14b.

For instance, since these areas are doped with different dopants, i.e., the n-type impurity and the p-type impurity, different spontaneous chemical reactions to the etchant manifests at the areas. Namely, a more pronounced spontaneous reaction to the etchant occurs at the n-type area 14a than at the p-type area, and this difference in the extent of the spontaneous reaction to the etchant becomes greater as the dope quantities of the dopants increase. As this chemical reaction speeds up the etching process at the n-type area, the side surfaces of the gate electrode at the n-type area 14a becomes etched (side-etched) more readily than the gate electrode at the p-type area 14b as shown in FIG. 4B). As a result, as shown in FIG. 4C, when the etching process at the p-type area 14b is completed, further side-etching will have taken place at the n-type area 14a, creating a greater difference between the shape of the gate electrode at the n-type area 14a and the shape of the gate electrode at the p-type area.

In addition, the etching speed changes depending upon the type of dopant. Namely, since the etching rate (etching speed) at the n-type area 14a is higher than that at the p-type area 14b, the etching process at the n-type area 14a is accelerated compared to the etching process at the p-type area 14b. Thus, when the main etching process is completed, the polysilicon film remains at the p-type area 14b and the gate oxide film 12 is not yet exposed, whereas the gate oxide film 12 is already exposed at the n-type area 14a as shown in FIG. 4B. This gives rise to a problem in that thinner the gate oxide film 12 the more readily a gate oxide film breakdown (gate oxide break) tends to occur at the n-type area 14a when the over-etching process is completed at the p-type area 14b. In particular, as the thickness of the gate oxide film at the base used during the process of forming, for instance, gate electrodes, is becoming increasingly small in order to miniaturize the elements to keep up with higher integration in semiconductor devices in recent years, the occurrence of gate oxide film breakdown is becoming more common.

Accordingly, an object of the present invention, which has been completed by addressing the problems discussed above, is to provide an etching method through which the inconsistency in the shapes of elements formed at areas such as an n-type area and a p-type area doped with different dopants or doped at different dope quantities can be minimized while preventing the occurrence of gate oxide film breakdown.

### SUMMARY OF THE INVENTION

In order to achieve the object described above, the present invention provides a new and improved etching method for simultaneously etching a p-type area doped with a p-type impurity and an n-type area doped with an n-type impurity at a processing target film layer formed over an insulating film layer formed at a workpiece in an airtight processing chamber.

Namely, in an aspect of the present invention, an etching method comprises a first etching step in which an etching process is executed on the processing target film layer until the insulating film becomes partially exposed by setting the pressure inside the processing chamber to 20 mTorr or lower, setting the high-frequency power applied to a lower electrode in said processing chamber to 0.15W/cm² or higher (e.g., approximately 50W or higher when processing a semiconductor wafer with a diameter of 200 mm), supplying a processing gas containing at least HBr gas into the processing chamber and using mask patterns as the mask and a second etching step in which an etching process is executed in order to remove portions of the processing target film layer having remained unetched during the first etching step with N₂ gas added into the processing gas.

Since this structure adopted in the present invention prompts a sputtering-induced etching process while disallowing rapid progress of the etching process induced by the chemical reaction and, as a result, elements such as gate electrodes formed through the etching steps at the individual areas on the workpiece are not side-etched to a great extent the inconsistency in the shapes of the elements formed at the various areas can be minimized.

In addition, in more practical terms, it is desirable to set the pressure inside the processing chamber to 10 mTorr or lower and to set the high-frequency power applied to the lower electrode to 0.3W/cm² or higher (e.g., approximately 100W or higher when processing a semiconductor wafer with a diameter of 200 mm) during the first etching step. Also, it is desirable set the flow rate ratio of the N₂ gas to the HBr gas to 0.5 or lower (50% or less) and it is even more desirable to set the flow rate ratio to 0.3 or lower (30% or less), during the second etching step.

In another aspect of the present invention, an etching method for simultaneously etching areas doped with different dopants or doped at different dope quantities at a processing target film layer over an insulating film layer formed at a workpiece in an airtight processing chamber comprises a first etching step in which an etching process is executed on the processing target film layer until the insulating film becomes partially exposed by setting the pressure inside the processing chamber to 20 mTorr or lower, setting the high-frequency power applied to a lower electrode in said processing chamber to 0.15W/cm² or higher, supplying a processing gas containing at least HBr gas into the processing chamber and using mask patterns as masks and a second etching step in which an etching process is executed in order to remove portions of the processing target film layer having remained unetched during the first etching step with N₂ gas added into the processing gas.

In yet another aspect of the present invention, an etching method for simultaneously etching a p-type area doped with a p-type impurity and an n-type area doped with an n-type impurity at a processing target film layer over an insulating film layer formed at a workpiece in an airtight processing chamber comprises a first etching step in which an etching process is executed on the processing target film layer until the insulating film becomes partially exposed by setting the pressure inside the processing chamber to 20 mTorr or lower, setting the high-frequency power applied to a lower electrode in said processing chamber to 0.15W/cm² or higher, supplying a processing gas containing at least HBr gas and an inert gas into the processing chamber and using mask patterns as masks and a second etching step in which an etching process is executed in order to remove portions of the processing target film layer having remained unetched during the first etching step. In this method, the flow rate ratio of the HBr gas to the overall flow rate of the processing gas may be set to 0.2-0.5 during the first etching step. In addition, the first etching step may be executed by using Ar gas as the inert gas. In such a case, it is desirable to set the flow rate ratio of the Ar gas to the HBr gas to 4 or lower.

By reducing the ratio of the HBr gas and adding an inert gas such as Ar gas into the processing gas used in the first etching step, the inconsistency in the shapes of the element formed at the n-type area and the element formed at the p-type area can be further reduced.

In yet another aspect of the present invention, an etching method for simultaneously etching a p-type area doped with a p-type impurity and an n-type area doped with an n-type impurity at a processing target film layer over an insulating film layer formed at a workpiece in an airtight processing chamber comprises a first etching step in which an etching process is executed on the processing target film layer until the insulating film becomes partially exposed by setting the pressure inside the processing chamber to 20 mTorr or lower, setting the high-frequency power applied to a lower electrode in said processing chamber to 0.15W/cm² or higher, supplying a processing gas containing at least HBr gas and N₂ gas into the processing chamber and using mask patterns as the mask and a second etching step in which an etching process is executed in order to remove portions of the processing target film layer having remained unetched during the first etching step. In this method, the flow rate ratio of the N₂ gas to the HBr gas may be set to 0.125 or higher during the first etching step.

Since the extent to which the element formed at the n-type area is side-etched can be reduced by adding the N₂ gas into the processing gas used in the first etching step, as described above, the inconsistency in the shapes of the element formed at the n-type area and the element formed at the p-type area can be further reduced.

In this specification, it is assumed that 1 mTorr is equal to (10⁻³×101325/760) Pa and that 1 sccm is equal to (10⁻⁶/60) m³/sec.

### BRIEF DESCRIPTION OF THE DRAWINGS

The above and other features of the invention and the concomitant advantages will be better understood and appreciated by persons skilled in the field to which the invention pertains in view of the following description given in conjunction with the accompanying drawings which illustrate preferred embodiments. In the drawings:

FIG. 1 schematically illustrates the structure of an etching apparatus in which the etching method may be adopted in an embodiment;

FIGS. 2A, 2B and 2C schematically shows the steps executed in the etching method in the embodiment;

FIGS. 3A and 3B shows shapes of gate electrodes achieved through a main etching process executed by adding N₂ gas into the processing gas in the embodiment; and

FIGS. 4A, 4B and 4C schematically shows the steps executed in plasma processing in the related art.

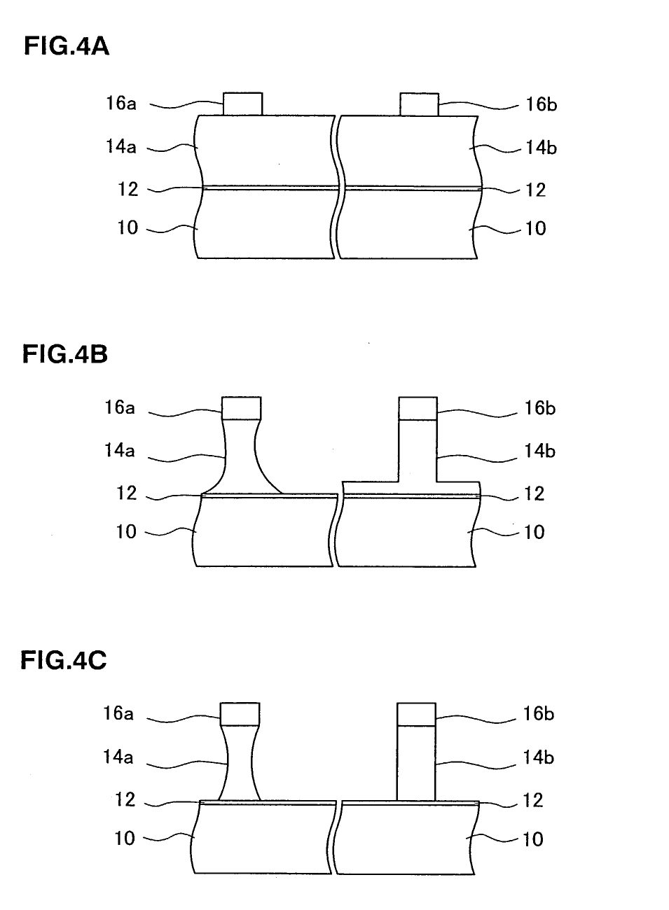

### DETAILED DESCRIPTION OF THE PREFERRED EMBODIMENT

The following is a detailed explanation of a preferred embodiment of the plasma processing apparatus according to the present invention, given in reference to the attached drawings. It is to be noted that in the specification and the drawings, the same reference numerals are assigned to components having substantially identical functions and structural features to preclude the necessity for a repeated explanation thereof.

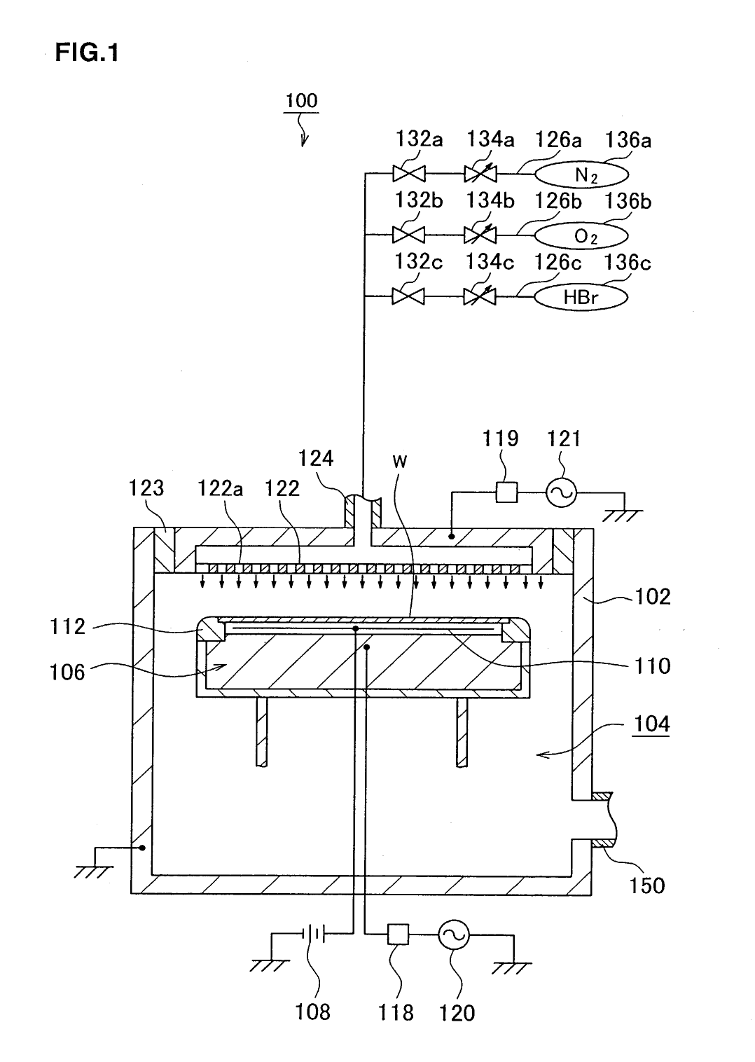

FIG. 1 schematically illustrates the structure of a plane-parallel type plasma etching apparatus representing etching apparatuses in which the etching method in the embodiment may be adopted.

In an etching apparatus 100, a processing chamber 104 is formed inside a processing container 102 which is grounded for safety, and a lower electrode 106 constituting a susceptor capable of moving up/down is provided inside the processing chamber 104. On top of the lower electrode 106, an electrostatic chuck 110 connected to a high voltage DC source 108 is provided, and a workpiece such as a semiconductor wafer (hereafter referred to as the “wafer”) W is placed on the top surface of the electrostatic chuck 110. In addition, a focus ring 112 with an insulating property is provided around the wafer W placed on the lower electrode 106. The lower electrode 106 is also connected with a second high-frequency source 120 via a matcher 118.

At the ceiling of the processing chamber 104, which faces opposite the surface of the lower electrode 106 at which the workpiece is placed, an upper electrode 122 having numerous gas outlet holes 122a is provided. An insulator 123 is provided between the upper electrode 122 and the processing container 102 to electrically isolate them from each other. The upper electrode 122 is also connected with a first high-frequency source 121 which outputs plasma generating high-frequency power via a matcher 119.

It is to be noted that first high-frequency power with a frequency of, for instance, 30 MHz or higher and preferably a frequency of 60 MHz is supplied to the upper electrode 122 from the first high-frequency source 121. In addition, second high-frequency power with a frequency lower than the frequency of the first high-frequency power, e.g., a frequency equal to or higher than 10 MHz and lower than 30 MHz, and preferably a frequency of 13.56 MHz, is supplied to the lower electrode 106 from the second high-frequency source 120.

A gas supply pipe 124 is connected to the gas outlet holes 122, a process gas supply system 126a that supplies, for instance, N₂ gas, a process gas supply system 126b that supplies O₂ gas and a process gas supply system 126c that supplies a gas containing at least H and Br, i.e., HBr gas to be more specific, are connected to the gas supply pipe 124.

The individual process gas supply systems 126a, 126b and 126c are respectively connected with a Cl₂ gas supply source 136a, O₂ gas supply source 136b and HBr gas supply source 136c via switching valves 132a, 132b and 132c and flow regulating valves 134a, 134b and 134c.

In addition, an evacuating pump 150 communicating with an evacuation mechanism (not shown) is connected near the bottom of the processing container 102, and with the evacuation mechanism engaged in operation, the pressure of the atmosphere inside the processing chamber 104 can be sustained at a specific lower level.

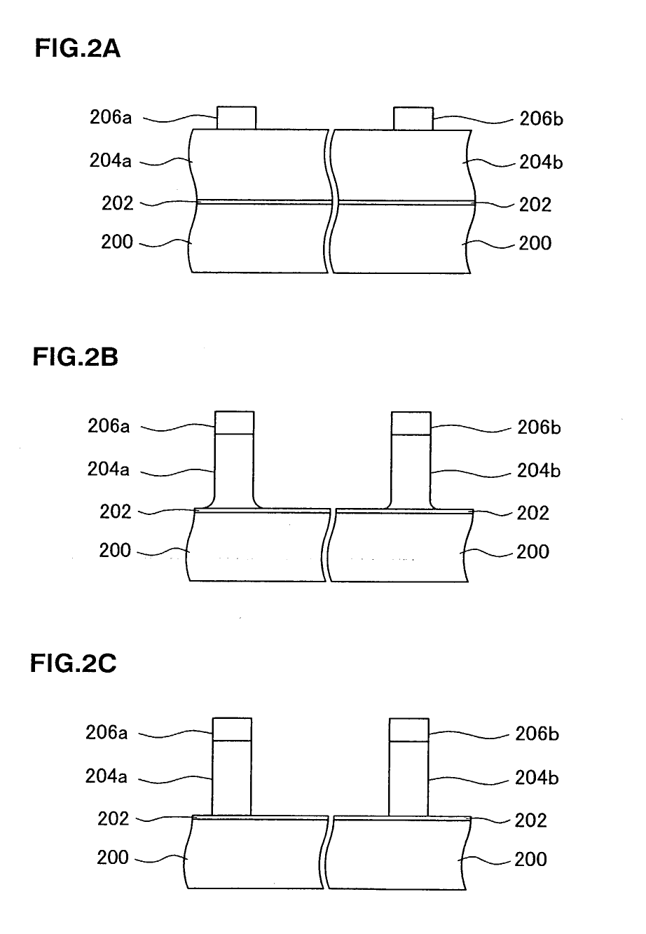

Next, in reference to FIGS. 2A, 2B and 2C, the steps executed when the etching method in the embodiment is adopted in conjunction with the etching apparatus described above are explained. First, a specific example of the film structure shown in FIG. 2A in conjunction with which the etching method according to the present invention is adopted is explained.

The film structure is achieved as follows. A gate oxide film 202 to act as an insulating film is formed at the upper surface of a silicon substrate 200 constituted of silicon, and a polysilicon film layer 204 constituted of poly-crystal silicon is laminated over the gate oxide film 202 through CVD (chemical vapor phase epitaxy) or the like. Next, phosphorus (P), which is an n-type impurity is selectively doped over the polysilicon film layer 204 constituting the processing target film layer, thereby forming an n-type area 204a, and also, boron (B), which is a p-type impurity is selectively doped over the polysilicon film layer 204, thereby forming a p-type area 204b. Then, mask patterns 206a and 206b which are so-called hard masks constituted of, for instance, TEOS (tetraethylortho silicate), NSG (non-doped silicate glass), SiN (silicon nitride) or the like are formed over the n-type area 204a and the p-type area 204b respectively.

The n-type area 204a and the p-type area 204b at the polysilicon film layer 204 achieving the film structure described above are now simultaneously etched. According to the present invention, a main etching step (a first etching step) is first executed and then, an over-etching step (a second etching step) is executed.

First, during the main etching step, the polysilicon film layer 204 is etched until the gate oxide film 202 becomes partially exposed with a processing gas containing at least HBr gas supplied into the airtight processing chamber 104. During the step, the polysilicon film layer 204 should be etched under conditions that promote the etching process through which the processing target surface is physically impacted, i.e., the etching process induced by the sputter phenomenon whereby ions in the plasma generated inside the processing chamber 104 collide with the processing target surface and excise atoms at the processing target surface rather than the etching process resulting from the chemical reaction between the processing target surface on the silicon substrate and the etchant. More specifically, the etching step should be executed by setting the pressure within the processing chamber 104 to a low level, e.g., 20 mTorr or lower so as to increase the ion energy in the plasma and by setting the level of the high-frequency power (the bias power) applied to the lower electrode 106 to 50 W or higher so as to achieve a high bias equivalent to the minimum of 0.15 W/cm² high-frequency power per unit wafer area.

Since these settings promote the sputter-induced etching process to progress while disallowing rapid progress of the chemical reaction-induced etching process, the gate electrodes formed at the individual areas 204a and 204b on the silicon substrate 200 through the etching step are not side-etched to a great extent and, as a result, the inconsistency in the shapes of the gate electrodes can be minimized, as shown in the FIG. 2B.

It is to be noted that the main etching step is executed until the gate oxide film 202 becomes partially exposed and that no gate oxide film breakdown occurs even when the selection ratio of the polysilicon film layer 204 relative to the gate oxide film 202 becomes low. Thus, while the selection ratio of the polysilicon film layer 204 relative to the gate oxide film 202 becomes lower as the pressure inside the processing chamber 104 is further lowered and the level of the high-frequency power applied to the lower electrode 106 is further raised to achieve a higher bias, the gate oxide film still remains intact. This means that the etching conditions described above can be ideally adopted during the main etching step in which the risk of a gate oxide breakdown is of no particular concern.

In addition, even if the main etching step is executed until the gate oxide film 202 becomes exposed to a greater extent under the conditions described above, no significant difference manifests between the etching rates (etching speed) at the areas 204a and 204b, and thus, the polysilicon film layer 204 is etched uniformly through both the area 204a and the area 204b, to prevent the occurrence of an oxide film breakdown. As a result, it becomes possible to prevent the occurrence of an oxide film breakdown caused by the use of different dopants even when the gate oxide film 202 becomes very thin.

The results of a test conducted to investigate how the etching rates at the n-type area 204a and the p-type area 204b at the polysilicon film layer 204 were affected when the necessary parameters of the etching conditions were varied are presented below.

While the ratio of the etching rates at the areas 204a and 204b at the polysilicon film should be ideally 1:1, it is difficult to achieve this ratio in reality. However, by setting the etching rate ratio as close as possible to 1, the inconsistency in the shapes of the elements formed through the etching process can be minimized and the occurrence of gate oxide film breakdown, too, can be prevented.

The reference etching conditions (first reference conditions) were; the pressure inside the processing chamber 104 set to 10 mTorr, the distance between the upper electrode 122 and the lower electrode 106 set to 100 mm, the flow rate ratio of the HBr gas and the O₂ gas (HBr gas flow rate/O₂ gas flow rate) set to 78 sccm/2 sccm, the pressure of the cooling gas set to 3 Torr both at the center and at the edge of the wafer rear surface, the temperature of the lower electrode set to 60° C., the temperature of the upper electrode set to 80° C. and the temperature at the side wall set to 60° C. in the processing chamber 104, the level of the high-frequency power applied to the upper electrode 122 set to 350 W and the level of the high-frequency power applied to the lower electrode 106 set to 75 W. It is to be noted that the test was conducted by using a gate oxide film having a film thickness of 15 Å (Å: angstrom). In addition, the wafer W had a diameter of 200 mm.

First, the ratio of the etching rates at the n-type area 204a and the p-type area 204b (etching rate at the n-type area 204a/etching rate at the p-type area 204b) during the etching process executed under the first reference conditions was approximately 1.258.

When an etching process was executed by increasing the high-frequency power (biasing power) applied to the lower electrode 106 which was 75 W in the first reference conditions to 150 W, the ratio of the etching rates at the n-type area 204a and the p-type area 204b (etching rate at the n-type area 204a/etching rate at the p-type area 204b) was approximately 1.100, becoming closer to 1. In other words, it was learned that by increasing the level of the high-frequency power (biasing power) applied to the lower electrode 106, the etching process induced by the sputter phenomenon can be prompted more aggressively while disallowing rapid progress of the chemical reaction-induced etching process.

When an etching process was executed by reducing the pressure inside the processing chamber 104 which was 10 mTorr in the first reference conditions to 5 mTorr, a ratio of approximately 1.049, which is viable for practical use, was achieved for the etching rates at the n-type area 204a and the p-type area 204b (etching rate at the n-type area 204a/etching rate at the p-type area 204b), and thus, the ratio became even closer to 1. In other words, it was learned that by lowering the pressure inside the processing chamber 104, the etching process induced by the sputter phenomenon can be further promoted and the progress of the etching process induced by the chemical reaction can be further suppressed.

It was learned through the test which was conducted further by varying the various parameters that a value viable for practical application can be achieved for the ratio of the etching rates at the, areas 204a and 204b when the conditions are set so as to promote the etching process induced by the sputter phenomenon but slow down the progress of the etching process induced by the chemical reaction, e.g., the pressure inside the processing chamber 104 set to 20 mTorr or lower, or as low as 10 mTorr or less to be more practical in application and the high-frequency power applied to the lower electrode 106 set equal to or higher than 0.15 W/cm²( e.g., 50 W or higher when processing a wafer with a 200 mm-diameter) or 0.3 W/cm² or higher (e.g., 100 W or higher when processing a 200 mm-diameter wafer) for a higher bias to be more viable in practical application.

Next, an over-etching step (a second etching step) is executed to etch the remaining polysilicon film layer 204 (at the tapered portions under the gate electrodes, etc.) by supplying a processing gas containing at least HBr gas into the airtight processing chamber 104. In the embodiment, N₂ gas is added into the processing gas. As a result, the side walls of the gate electrodes are protected by the N₂ gas and the progress of the etching process induced by the chemical reaction at the side walls of the gate electrodes which have already been etched is slowed down to minimize the extent to which the gate electrodes become side-etched during the over-etching step. However, if the flow rate ratio of the N₂ gas to the HBr gas is too high, and etch stop or a reduction in the selection ratio relative to the gate oxide film will result. Thus, it is desirable to set the flow rate ratio of the N₂ gas to the HBr gas to 0.5 or lower (50% or less), for instance, to ensure that the process of the side-etching at the side walls of the gate electrodes is slowed down while no etch stop occurs at other areas such as the lower portions of the gate electrodes, or it is even more desirable to set the flow rate ratio to 0.3 or lower (30% or less) for further practical viability.

In addition, it is more desirable to set the pressure inside the processing chamber 104 to a low level of 20 mTorr or less during this over-etching step as well so as to sustain the high sputtering force while suppressing the chemical reaction.

Since it is not necessary to raise the high-frequency power applied to the lower electrode in this case, the selection ratio of the polysilicon film layer 204 relative to the gate oxide film 202 is not lowered and, consequently, the occurrence of a gate oxide film breakdown during the over-etching step can be prevented.

The conditions for the over-etching step include, for instance, the pressure inside the processing chamber 104 set to 10 mTorr, the distance between the upper electrode 122 and the lower electrode 106 set to 120 mm, the flow rate ratio of HBr gas/O₂ gas/N₂ gas (HBr gas flow rate/O₂ gas flow rate/N₂ gas flow rate) set to 30 sccm/2 sccm/5 sccm, the pressure of the cooling gas set to 20 Torr both at the center and at the edge of the wafer rear surface, the temperature of the lower electrode set to 60° C., the temperature of the upper electrode set to 80° C. and the temperature at the side wall set to 60° C. inside the processing chamber 104, the high-frequency power applied to the upper electrode 122 set to 100 W and the high-frequency power applied to the lower electrode 106 set to 75 W.

By executing such an over-etching step, gate electrodes achieving near perfect uniformity in their shapes can be formed at the n-type area 204a and the p-type area 204b as shown in FIG. 2C.

Next, an example in which a processing gas achieved by lowering the flow rate of the HBr gas and adding an inert gas is used in the main etching step (the first etching step) is explained. As described earlier, by selecting the correct level of high-frequency power to be applied to the lower electrode 106 and the correct level of pressure inside the processing chamber 104 as the etching conditions, the inconsistency in the shapes of the element formed at the n-type area and the element formed at the p-type area can be minimized.

When the etching conditions include a processing gas achieved by lowering the flow rate of the HBr gas and adding an inert gas, the inconsistency in the shapes of the element formed at the n-type area and the element formed at the p-type area can be further reduced. This is considered to be attributable to a reduction in the HBr radicals achieved by lowering the flow rate of the HBr gas, which further slows down the etching process induced by the chemical reaction and a faster progress of the etching process induced by the sputter phenomenon achieved by the addition of the inert gas such as Ar gas into the processing gas.

The following is an explanation of the results of a test conducted by executing the main etching step (the first etching step) on a film structure similar to that shown in FIG. 2A. The reference etching conditions (second reference conditions) were; the pressure inside the processing chamber 104 set to 5 mTorr, the distance between the upper electrode 122 and the lower electrode 106 set to 100 mm, the flow rate ratio of the HBr gas/the O₂ gas (HBr gas flow rate/O₂ gas flow rate) set to 99 sccm/1 sccm, the pressure of the cooling gas set to 10 Torr both at the center and at the edge of the wafer rear surface, the temperature of the lower electrode set to 70° C., the temperature of the upper electrode set to 80° C. and the temperature at the side wall set to 60° C. in the processing chamber 104, the level of the high-frequency power applied to the upper electrode 122 set to 100 W and the level of the high-frequency power applied to the lower electrode 106 set to 100 W. In addition, the wafer W had a diameter of 200 mm.

The ratio of the etching rates at the n-type area 204a and the p-type area 204b (etching rate at the n-type area 204a/etching rate at the p-type area 204b) during the etching process executed under the second reference conditions was approximately 1.11.

A main etching step was executed by reducing the flow rate of the HBr gas constituting the second reference condition and adding Ar gas to make up for the lowered HBr gas flow rate so as to achieve a flow rate ratio for the Ar gas/the HBr gas (Ar gas flow rate/HBr gas flow rate) of, for instance, 50 sccm/49 sccm. In this case, a ratio of 756 (Å/min)/733 (Å/min) i.e., approximately 1.03, was achieved for the etching rates at the n-type area 204a and the p-type area 204b (etching rate at the n-type area 204a/etching rate at the p-type area 204b), which was even closer to 1.

Next, a main etching step was executed by further reducing the flow rate of the HBr gas and adding more Ar gas to make up for the lowered HBr gas flow rate so as to achieve a flow rate ratio for the Ar gas/the HBr gas (Ar gas flow rate/HBr gas flow rate) of, for instance, 80 sccm/20 sccm. In this case, a ratio of 533 (Å/min)/521 (Å/min) i.e., approximately 1.02, was achieved for the etching rates at the n-type area 204a and the p-type area 204b (etching rate at the n-type area 204a/etching rate at the p-type area 204b), which was even closer to 1.

While the chemical reaction-induced etching process can be slowed down by reducing the HBr gas as described above, if the flow rate of the HBr gas is lowered to an excessive degree, a complete etch stop will occur or the progress of the main etching process itself will be slowed down. Thus, it is desirable from a practical point of view to maintain the flow rate ratio of the HBr gas to the flow rate of the entire processing gas within a range of 20%-50% (0.2-0.5) and to set a flow rate ratio of the Ar gas to the HBr gas to 4 or higher.

Next, an example in which a processing gas containing N₂ gas is used during the main etching step (the first etching step) is explained. As described earlier, by adding the N₂ gas into the processing gas in the over-etching step, the inconsistency in the shapes of the element formed at the n-type area and the element formed at the p-type area can be reduced. The N₂ gas may also be added into the processing gas in the main etching step to further reduce the inconsistency in the shapes of the element formed at the n-type area and the element formed at the p-type area. This is considered to be attributable to the formation of an SiN protective film at the side walls of the gate electrodes, which is achieved by adding the N₂ gas into the processing gas for the main etching step.

The following is an explanation of the results of a test conducted by executing the main etching step (the first etching step) after a breakthrough etching process which was performed to remove the natural oxide film formed at the exposed surface of the polysilicon film layer 204. The breakthrough etching conditions were; the pressure inside the processing chamber 104 set to 10 mTorr, the distance between the upper electrode 122 and the lower electrode 106 set to 80 mm, a mixed gas containing CF₄ gas and Ar gas used as the processing gas with the flow rate ratio of the CF₄ gas/the Ar gas (CF₄ gas flow rate/Ar gas flow rate) set to 50 sccm/150 sccm, the pressure of the cooling gas set to 3 Torr both at the center and at the edge of the wafer rear surface, the temperature of the lower electrode set to 75° C., the temperature of the upper electrode set to 80° C. and the temperature at the side wall set to 60° C. in the processing chamber 104, the level of the high-frequency power applied to the upper electrode 122 set to 350 W and the level of the high-frequency power applied to the lower electrode 106 set to 150 W. The breakthrough etching process was executed only for a period of 5 sec.

The reference etching conditions (third reference conditions) for the main etching step were; the pressure inside the processing chamber 104 set to 10 mTorr, the distance between the upper electrode 122 and the lower electrode 106 set to 100 mm, the flow rate ratio of the HBr gas/the O₂ gas/the Ar gas used to constitute the processing gas (HBr gas flow rate/O₂ gas flow rate/Ar gas flow rate) set to 120 sccm/1 sccm/180 sccm, the pressure of the cooling gas set to 3 Torr at the center and 10 Torr at the edge of the wafer rear surface, the temperature of the lower electrode set to 70° C., the temperature of the upper electrode set to 80° C. and the temperature at the side wall set to 60° C. in the processing chamber 104, the level of the high-frequency power applied to the upper electrode 122 set to 100 W and the level of the high-frequency power applied to the lower electrode 106 set to 120 W. The main etching step was executed only over a period of 43 sec. In addition, the wafer W had a diameter of 200 mm.

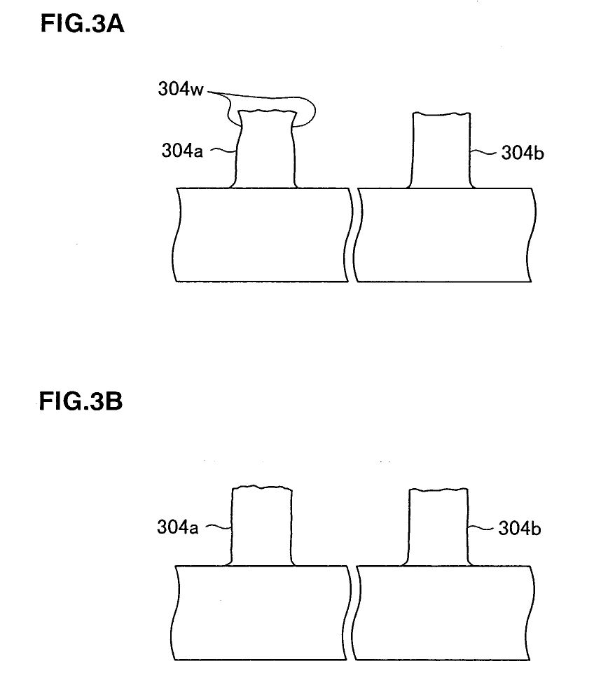

When the etching step was executed under the third reference conditions, inconsistency in the shapes of the gate electrodes manifested as shown in FIG. 3A since side-etching occurred at the upper side wall of the gate electrode at the n-type area 304a whereas no side-etching occurred at the gate electrode at the p-type area 304b.

However, as the third reference conditions were modified by adding N₂ gas into the processing gas and the flow rate of the N₂ gas was gradually raised from 9 sccm to 12 sccm, and then to 15 sccm, the inconsistency in the shapes disappeared. For instance, while the shapes were still inconsistent when the flow rate of the N₂ gas was 9 sccm or 12 sccm, the upper side wall 304w of the gate electrode at the n-type area 304a was no longer side-etched, as shown in FIG. 3B, once the flow rate of the N₂ gas reached 15 sccm and since the gate electrode at the p-type area 304b was not side-etched, the inconsistency in the shapes became almost indiscernible. As explained above, by adding the N₂ gas into the processing gas used in the main etching step, too, the inconsistency in the shapes of the element formed at the n-type area and the element formed at the p-type area can be further reduced.

As explained above, the inconsistency in the shapes becomes less discernible as the flow rate of the N₂ gas is raised. However, from a practical point of view, satisfactory results can be achieved as long as the flow rate ratio of the N₂ gas to the HBr gas is at least 0.125. In addition, the flow rate of the N₂ gas added into the processing gas for the main etching step can be higher than the flow rate of the N₂ gas added for the over-etching step, since it is not necessary to factor in the risk of an oxide film breakdown or the like during the main etching step and consequently, other conditions such as the level of the high-frequency power applied to the lower electrode can be adjusted to a certain extent.

As explained above, by setting the correct processing conditions individually for the main etching step and the over-etching step, the inconsistency in the shapes of the elements formed at the n-type area and the p-type area through simultaneous etching of these areas can be minimized and, ultimately, occurrence of gate oxide film breakdown can be prevented.

While the invention has been particularly shown and described with respect to preferred embodiment thereof by referring to the attached drawings, the present invention is not limited to this example and it will be understood by those skilled in the art that various changes in form and detail may be made therein without departing from the spirit, scope and teaching of the invention.

For instance, while an explanation is given above in reference to the embodiment on an example in which the present invention is adopted in a plasma etching apparatus that separately applies high-frequency power to the upper electrode 122 and the lower electrode 106, the present invention is not limited to this example and it may be adopted in, for instance, a plasma etching apparatus in which high-frequency power is applied to the lower electrode alone.

In addition, while an explanation is given above in reference to the embodiment on an example in which a polysilicon film layer constituting the processing target film layer on an insulating film is etched, the present invention is not limited to this example and the processing target film may be constituted of another type of poly-crystal silicon or it may be constituted of a silicon film layer such as a polycide film layer adopting, for instance, a WSi/Poly/Ox structure, or the present invention may be adopted to metal-etch a metal layer adopting a W/WN/Poly/Ox structure or the like.

Furthermore, while an explanation is given above in reference to the embodiment on an example in which the n-type area is doped with phosphorus used as the n-type impurity and the p-type area is doped with boron used as the p-type impurity, elements other than these may be used as the n-type impurity and the p-type impurity, instead. Also, the n-type area may be doped with phosphorus used as the n-type impurity, for instance, and the p-type area may be an area which is not doped with any impurity or phosphorus may be doped in both areas at different dope quantities.

As explained in detail above, according to the present invention, when elements such as gate electrodes are formed at areas doped with different dopants, e.g., a p-type area doped with a p-type impurity and an n-type area doped with an n-type impurity, or areas with different dope quantities, e.g., an n-type area doped with an n-type impurity and a p-type area with no dopant, by simultaneously etching these areas at the processing target film layer on an insulating film formed on a workpiece, the inconsistency in the shapes of the elements at the individual areas can be minimized and the occurrence of a gate oxide film breakdown can be prevented.

What is claimed is;

1. An etching method for simultaneously etching a p-type area doped with a p-type impurity and an n-type area doped with an n-type impurity at a processing target film layer formed over an insulating film layer formed at a workpiece in an airtight processing chamber comprising:
a first etching step in which an etching process is executed on said processing target film layer until said insulating film becomes partially exposed by setting the pressure inside said processing chamber to 20 mTorr or lower, setting the high-frequency power. applied to a lower electrode in said processing chamber to 0.15W/cm² or higher, supplying a processing gas containing at least HBr gas into said processing chamber and using mask patterns as masks; and
a second etching step in which an etching process is executed in order to remove portions of said processing target film layer having remained unetched during said first etching step with N₂ gas added into said processing gas.

2. An etching method according to claim 1, wherein:
said first etching step is executed by setting the pressure inside said processing chamber to 10 mTorr or lower and setting the high-frequency power applied to said lower electrode to 0.3 W/Cm² or higher.

3. An etching method according to claim 1, wherein:
said second etching step is executed by setting the flow rate ratio of the N₂ gas to the HBr gas to 0.5 or lower.

4. An etching method according to claim 1, wherein:
said second etching step is executed by setting the flow rate ratio of the N₂ gas to the HBr gas to 0.3 or lower.

5. An etching method for simultaneously etching areas doped with different dopants or doped at different dope quantities at a processing target film layer over an insulating film layer formed at a workpiece in an airtight processing chamber comprising:
a first etching step in which an etching process is executed on said processing target film layer until said insulating film becomes partially exposed by setting the pressure inside said processing chamber to 20 mTorr or lower, setting the high-frequency power applied to a lower electrode in said processing chamber to 0.15W/cm² or higher, supplying a processing gas containing at least HBr gas into said processing chamber and using mask patterns as masks; and
a second etching step in which an etching process is executed in order to remove portions of said processing target film layer having remained unetched during said first etching step with N₂ gas added into said processing gas.

6. An etching method for simultaneously etching a p-type area doped with a p-type impurity and an n-type area doped with an n-type impurity at a processing target film layer over an insulating film layer formed at a workpiece in an airtight processing chamber comprising:
a first etching step in which an etching process is executed on said processing target film layer until said insulating film becomes partially exposed by setting the pressure inside said processing chamber to 20 mTorr or lower, setting the high-frequency power applied to a lower electrode in said processing chamber to 0.15W/cm² or higher, supplying a processing gas containing at least HBr gas and an inert gas into said processing chamber and using mask patterns as masks; and
a second etching step in which an etching process is executed in order to remove portions of said processing target film layer having remained unetched during said first etching step.

7. An etching method according to claim 6, wherein:
said first etching step is executed by setting the flow rate ratio of the HBr gas to the overall flow rate of the processing gas to 0.2-0.5.

8. An etching method according to claim 6, wherein:
said first etching step is executed by using Ar gas as said inert gas.

9. An etching method according to claim 6, wherein:
said first etching step is executed by using Ar gas as said inert gas; and
the flow rate ratio of the Ar gas to the HBr gas is set to 4 or lower.

10. An etching method for simultaneously etching a p-type area doped with a p-type impurity and an n-type area doped with an n-type impurity at a processing target film layer over an insulating film layer formed at a workpiece in an airtight processing chamber comprising:
a first etching step in which an etching process is executed on said processing target film layer until said insulating film becomes partially exposed by setting the pressure inside said processing chamber to 20 mTorr or lower, setting the high-frequency power applied to a lower electrode in said processing chamber to 0.15W/cm² or higher, supplying a processing gas containing at least HBr gas and N₂ gas into said processing chamber and using mask patterns as masks; and
a second etching step in which an etching process is executed in order to remove portions of said processing target film layer having remained unetched during said first etching step.

11. An etching method according to claim 10, wherein:
said first etching step is executed by setting the flow rate ratio of N₂ gas to the HBr gas to 0.125 or higher.
